(19) United States
(12) Patent Application Publication
(10) Pub. No.: US 2023/0393483 A1
(43) Pub. Date: Dec. 7, 2023

(54) HEAT TREATMENT APPARATUS, HEAT TREATMENT METHOD, AND RECORDING MEDIUM

(71) Applicant: Tokyo Electron Limited, Tokyo (JP)

(72) Inventor: Shinichiro Kawakami, Koshi City (JP)

(21) Appl. No.: 18/326,266

(22) Filed: May 31, 2023

(30) Foreign Application Priority Data
Jun. 2, 2022 (JP) 2022-090446

(51) Int. Cl. G03F 7/36; H01L 21/3105

(52) U.S. Cl. CPC G03F 7/36; H01L 21/3105

(57) ABSTRACT

A heat treatment apparatus configured to heat-treat a substrate having a metal-containing resist film formed thereon includes a heat plate configured to support and heat the substrate; a chamber in which the heat plate is accommodated and a processing space in which a heat treatment is performed is formed; an exhaust unit configured to evacuate an inside of the processing space; and a supply mechanism configured to supply a gas into the processing space. The supply mechanism supplies, into the processing space, a high concentration gas whose CO₂ concentration is adjusted to be higher than that of an ambient atmosphere around the chamber.

### CROSS-REFERENCE TO RELATED APPLICATION

This application claims the benefit of Japanese Patent Application No. 2022-090446 filed on Jun. 2, 2022, the entire disclosure of which is incorporated herein by reference.

### TECHNICAL FIELD

The various aspects and embodiments described herein pertain generally to a heat treatment apparatus, a heat treatment method, and a recording medium.

### BACKGROUND

Patent Document 1 describes a technique in which a substrate having a metal-containing resist film formed thereon is heated after being subjected to an exposure processing.
Patent Document 1: Japanese Patent Laid-open Publication No. 2018-098229

### SUMMARY

In one exemplary embodiment, there is provided a heat treatment apparatus configured to heat-treat a substrate having a metal-containing resist film formed thereon. The heat treatment apparatus includes a heat plate configured to support and heat the substrate; a chamber in which the heat plate is accommodated and a processing space in which a heat treatment is performed is formed; an exhaust unit configured to evacuate an inside of the processing space; and a supply mechanism configured to supply a gas into the processing space. The supply mechanism supplies, into the processing space, a high concentration gas whose CO₂ concentration is adjusted to be higher than that of an ambient atmosphere around the chamber.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is an explanatory diagram illustrating an outline of an internal configuration of a coating and developing system as a substrate processing system, including a heat treatment apparatus according to a first exemplary embodiment;

FIG. 2 is a diagram illustrating an outline of an internal configuration of a front side of the coating and developing system;

FIG. 3 is a diagram illustrating an outline of an internal configuration of a rear side of the coating and developing system;

FIG. 4 is a longitudinal cross-sectional view schematically illustrating an outline of a configuration of a heat treatment apparatus configured to perform a PEB treatment;

FIG. 5 is a bottom view schematically illustrating an outline of a configuration of an upper chamber;

FIG. 6A and FIG. 6B are diagrams illustrating states of the heat treatment apparatus of FIG. 4 during a wafer processing performed by using this heat treatment apparatus;

FIG. 7A and FIG. 7B are diagrams illustrating states of the heat treatment apparatus of FIG. 4 during the wafer processing performed by using this heat treatment apparatus;

FIG. 8 is a diagram illustrating a state of the heat treatment apparatus of FIG. 4 during the wafer processing performed by using this heat treatment apparatus;

FIG. 9 is a diagram illustrating line widths of a resist pattern in individual areas of a wafer, which is obtained by a PEB treatment according to a comparative example;

FIG. 10 is a diagram illustrating line widths of a resist pattern in individual areas of a wafer, which is obtained by the PEB treatment according to the comparative example;

FIG. 11 is a longitudinal cross-sectional view schematically illustrating an outline of a configuration of a heat treatment apparatus according to a second exemplary embodiment;

FIG. 12 is a longitudinal cross-sectional view schematically illustrating an outline of a configuration of a heat treatment apparatus according to a third exemplary embodiment; and

FIG. 13 is a diagram illustrating an effect of a modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In a manufacturing process for a semiconductor device or the like, a preset processing is performed on a substrate such as a semiconductor wafer (hereinafter, simply referred to as “wafer”) to form a resist pattern on the substrate. The preset processing is, for example, a resist coating processing of forming a film of a resist by supplying a resist liquid onto the substrate, an exposure processing of exposing the film, a developing processing of developing the exposed film, or the like. In addition, the preset processing also includes a heat treatment such as a PEB (Post Exposure Bake) treatment in which the film is heated before being subjected to the developing processing and after being subjected to the exposure processing to thereby accelerate a chemical reaction within the film.

In recent years, a metal-containing resist may be used as the resist instead of a chemically amplified resist. In this case, the result of the heat treatment may not be stable. Specifically, even if heat treatment conditions are the same, a size of a resist pattern may differ depending on the timing when the heat treatment is performed. For example, the size of the resist pattern may be different between heat treatments performed at different times on the same day or on different days.

In this regard, as a result of intensive studies performed by the present inventors, it has been found out that the size of the resist pattern is changed by being affected by the conditions around a heat treatment apparatus when the heat treatment is performed. Specifically, it has been found out that the size of the resist pattern is changed by being affected by a CO₂ concentration around the heat treatment apparatus at the time when the heat treatment is performed.

In view of the foregoing, the present disclosure provides a technique capable of stabilizing the result of the heat treatment on the substrate on which the film of the metal-containing resist is formed.

Hereinafter, a heat treatment apparatus and a heat treatment method according to exemplary embodiments will be described with reference to the accompanying drawings. In the present specification and drawings, parts having substantially the same functions and configurations will be assigned same reference numerals, and redundant description will be omitted.

### First Exemplary Embodiment

<Coating and Developing System>

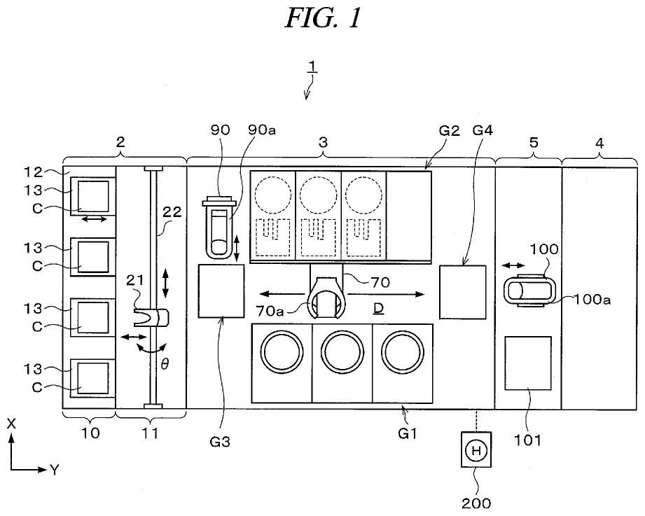

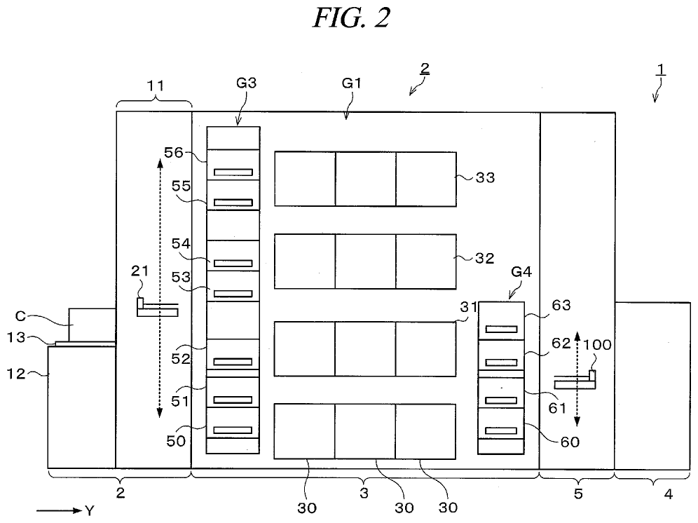

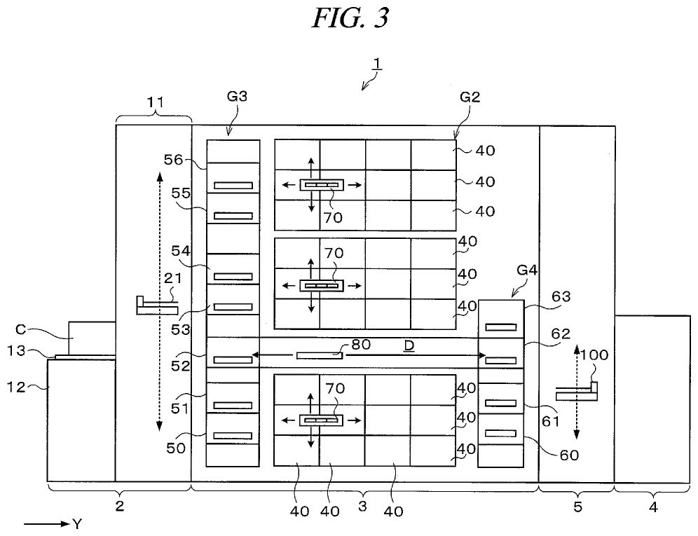

FIG. 1 is an explanatory diagram illustrating an outline of an internal configuration of a coating and developing system as a substrate processing system, including a heat treatment apparatus according to a first exemplary embodiment. FIG. 2 and FIG. 3 are diagrams illustrating an outline of internal configurations of a front side and a rear side of the coating and developing system, respectively.

A coating and developing system 1 is configured to form a resist pattern on a wafer W as a substrate by using a metal-containing resist. In the present exemplary embodiment, after being hydrolyzed by reacting with CO₂ and moisture in the ambient atmosphere or the like, the metal-containing resist is crosslinked by dehydration condensation to be solidified. Further, the metal contained in the metal-containing resist is not particularly limited. For example, it may be tin.

The coating and developing system 1 includes, as shown in FIG. 1 to FIG. 3, a cassette station 2 in which a cassette C, which is a container capable of accommodating a plurality of wafers W therein, is carried in and out; and a processing station 3 equipped with various kinds of processing apparatuses each configured to perform a preset processing such as a resist coating processing. The coating and developing system 1 has a configuration in which the cassette station 2, the processing station 3, and an interface station 5 serving to deliver the wafer W to/from an exposure apparatus 4 adjacent to the processing station 3 are connected as one body.

The cassette station 2 is divided into, for example, a cassette carry-in/out section 10 and a wafer transfer section 11. By way of example, the cassette carry-in/out section 10 is provided at an end portion of the coating and developing system 1 on the negative Y-axis side (left side of FIG. 1). A cassette placing table 12 is provided in the cassette carry-in/out section 10. A plurality of, for example, four placing plates 13 are provided on the cassette placing table 12. The placing plates 13 are arranged in a row in a horizontal X-axis direction (up-and-down direction of FIG. 1). Cassettes C can be placed on these placing plates 13 when the cassettes are carried into or out of the coating and developing system 1.

The wafer transfer section 11 is provided with a transfer device 21 configured to transfer the wafer W. The transfer device 21 is configured to be movable along a transfer path 22 extending in the X-axis direction. The transfer device 21 is also movable in a vertical direction and pivotable around a vertical axis (θ direction), and is capable of transferring the wafer W between the cassette C on each placing plate 13 and a transit device of a third block G3 of the processing station 3 to be described later.

The processing station 3 is provided with a plurality of, for example, first to fourth blocks G1, G2, G3, and G4 each of which is equipped with various kinds of apparatuses. By way of example, the first block G1 is provided on the front side (negative X-axis side of FIG. 1) of the processing station 3, and the second block G2 is provided on the rear side (positive X-axis side of FIG. 1) of the processing station 3. Further, the third block G3 is provided on the cassette station 2 side (negative Y-axis side of FIG. 1) of the processing station 3, and the fourth block G4 is provided on the interface station 5 side (positive Y-axis side of FIG. 1) of the processing station 3.

In the first block G1, a plurality of liquid processing apparatuses, for example, a developing apparatus 30, a lower anti-reflection film forming apparatus 31, a resist coating apparatus 32, and an upper anti-reflection film forming apparatus 33 are arranged in this order from the bottom, as illustrated in FIG. 2. The developing apparatus 30 is configured to perform a developing processing on the wafer W. Specifically, the developing apparatus 30 performs the developing processing on a film of a metal-containing resist, that is, a metal-containing resist film of the wafer W after being subjected to a PEB treatment. The lower anti-reflection film forming apparatus 31 is configured to form an anti-reflection film (hereinafter referred to as “lower anti-reflection film”) under the metal-containing resist film of the wafer W. The resist coating apparatus 32 is configured to perform a resist coating processing of forming the metal-containing resist film by coating the metal-containing resist on the wafer W. The upper anti-reflection film forming apparatus 33 is configured to form an anti-reflection film (hereinafter referred to as “upper anti-reflection film”) on the metal-containing resist film of the wafer W.

For example, three developing apparatuses 30, three lower anti-reflection film forming apparatuses 31, three resist coating apparatuses 32, and three upper anti-reflection film forming apparatuses 33 are arranged horizontally. However, the number and the layout of the developing apparatuses 30, the lower anti-reflection film forming apparatuses 31, the resist coating apparatuses 32, and the upper anti-reflection film forming apparatuses 33 can be selected as required.

In each of the developing apparatus 30, the lower anti-reflection film forming apparatus 31, the resist coating apparatus 32, and the upper anti-reflection film forming apparatus 33, a predetermined processing liquid is coated on the wafer W by, for example, a spin coating method. For example, in the spin coating method, the processing liquid is discharged onto the wafer W from a discharge nozzle, and the processing liquid is diffused on the surface of the wafer W by rotating the wafer W.

For example, in the second block G2, heat treatment apparatuses 40 each configured to heat-treat the wafer W are arranged vertically and horizontally, as illustrated in FIG. 3. The number and the layout of the heat treatment apparatuses 40 can also be selected as required. Further, the heat treatment apparatus 40 performs a pre-baking treatment (hereinafter, referred to as “PAB treatment”) of heat-processing the wafer W after being subjected to the resist coating processing, a PEB treatment of heat-processing the wafer W after being subjected to the exposure processing, a post-baking treatment (hereinafter, referred to as “POST treatment”) of heat-processing the wafer W after being subjected to the developing processing.

For example, in the third block G3, a plurality of transit devices 50, 51, 52, 53, 54, 55, and 56 are arranged in sequence from the bottom. Further, in the fourth block G4, a plurality of transit devices 60, 61, and 62 and a rear surface cleaning apparatus 63 configured to clean the rear surface of the wafer W are arranged in sequence from the bottom.

As depicted in FIG. 1, a wafer transfer region D is formed in an area surrounded by the first to fourth blocks G1 to G4. The wafer transfer region D is provided with, for example, a transfer device 70 serving as a substrate transfer device configured to transfer the wafer W.

The transfer device 70 has a transfer arm 70a configured to be movable in, for example, the Y-axis direction, the θ direction, and the vertical direction, for example. The transfer device 70 is capable of transferring the wafer W to preset apparatuses within the first block G1, the second block G2, the third block G3 and the fourth block G4 by moving the transfer arm 70a holding the wafer W within the wafer transfer region D. As illustrated in FIG. 3, a plurality of transfer devices 70 are vertically arranged to transfer the wafers W to, for example, preset apparatuses of the respective blocks G1 to G4 on the same height.

Further, in the wafer transfer region D, there is provided a shuttle transfer device 80 configured to transfer the wafers W linearly between the third block G3 and the fourth block G4.

The shuttle transfer device 80 linearly moves the wafer W in the Y-axis direction, thus allowing the wafer W to be transferred between a transfer device 52 of the third block G3 and a transfer device 62 of the fourth block G4 on the substantially same height.

As depicted in FIG. 1, a transfer device 90 is provided on the positive X-axis side of the third block G3. The transfer device 90 has a transfer arm 90a configured to be movable in the θ direction and the vertical direction, for example. The transfer device 90 is capable of transferring the wafer W to the respective transit devices in the third block G3 by vertically moving the transfer arm 90a holding the wafer W thereon.

The interface station 5 is equipped with a transfer device 100 and a transit device 101. The transfer device 100 has a transfer arm 100a configured to be movable in the θ direction and the vertical direction, for example. The transfer device 100 is capable of transferring the wafer W between the respective transit devices in the fourth block G4, the transit device 101, and the exposure apparatus 4 while holding the wafer W on the transfer arm 100a.

The coating and developing system 1 described above has a controller 200, as shown in FIG. 1. The controller 200 is, for example, a computer equipped with a processor such as a CPU and a memory, and has a program storage (not shown). The program storage stores therein programs for controlling a wafer processing to be described later by controlling operations of a driving system such as the various kinds of transfer devices and the various kinds of processing apparatuses described above. In addition, the program may be recorded in a computer-readable recording medium H and installed from the recording medium H to the controller 200. The recording medium H may be temporary or non-temporary. Some or all of the programs may be implemented by dedicated hardware (circuit board).

<Wafer Processing Using Coating and Developing System 1>

Now, an example of the wafer processing using the coating and developing system 1 will be explained. The following processing is performed under the control of the controller 200.

First, the cassette accommodating the plurality of wafers W therein is carried into the cassette station 2 of the coating and developing system 1 and placed on the placing plate 13. Then, the wafers W within the cassette C are sequentially taken out by the transfer device 21 and transferred to the transit device 53 of the third block G3 of the processing station 3.

Then, the wafer W is transferred to the heat treatment apparatus 40 of the second block G2 by the transfer device 70 to be temperature-controlled. Thereafter, the wafer W is transferred by the transfer device 70 to, for example, the lower anti-reflection film forming apparatus 31 of the first block G1, and the lower anti-reflection film is formed on the wafer W. Then, the wafer W is transferred to the heat treatment apparatus 40 of the second block G2 to be subjected to a heating processing. Afterwards, the wafer W is returned to the transit device 53 of the third block G3.

Next, the wafer W is transferred to the resist coating apparatus 32 by the transfer device 70, and the metal-containing resist film is formed on the wafer W. Afterwards, the wafer W is transferred to the heat treatment apparatus 40 by the transfer device 70 to be subjected to the PAB treatment. Then, the wafer W is transferred to the transit device 55 of the third block G3 by the transfer device 70.

Subsequently, the wafer W is transferred to the upper anti-reflection film forming apparatus 33 by the transfer device 70, and the upper anti-reflection film is formed on the wafer W. Then, the wafer W is transferred to the heat treatment apparatus by the transfer device 70 to be heated and temperature-controlled.

Afterwards, the wafer W is transferred to the transit device 56 of the third block G3 by the transfer device 70.

Next, the wafer W is transferred to the transit device 52 by the transfer device 90 and is then transferred to the transit device 62 of the fourth block G4 by the transfer device 80. Afterwards, the wafer W is transferred to the rear surface cleaning apparatus 63 by the transfer device 100, and the rear surface of the wafer W is cleaned. Subsequently, the wafer W is transferred to the exposure apparatus 4 by the transfer device 100 of the interface station 5, and is exposed to a preset pattern by using EUV light.

Next, the wafer W is transferred to the transit device 60 of the fourth block G4 by the transfer device 100. Thereafter, the wafer W is transferred to the heat treatment apparatus 40 to be subjected to the PEB treatment.

Subsequently, the wafer W is transferred to the developing apparatus 30 by the transfer device 70 to be developed. Upon the completion of the development, the wafer W is transferred to the heat treatment apparatus 40 by the transfer device 70 to be subjected to the POST treatment.

Then, the wafer W is transferred to the transit device 50 of the third block G3 by the transfer device 70, and is then transferred to the cassette C on the preset placing plate 13 by the transfer device 21 of the cassette station 2. In this way, a series of photolithography processes is completed.

<Heat Treatment Apparatus>

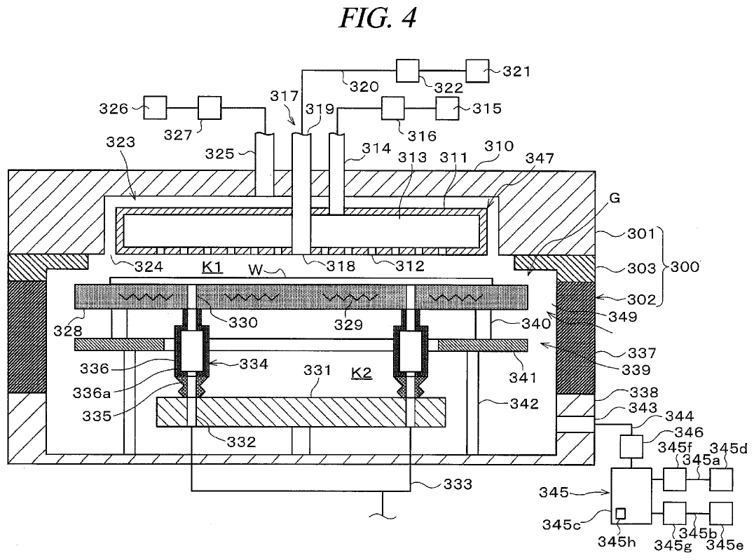

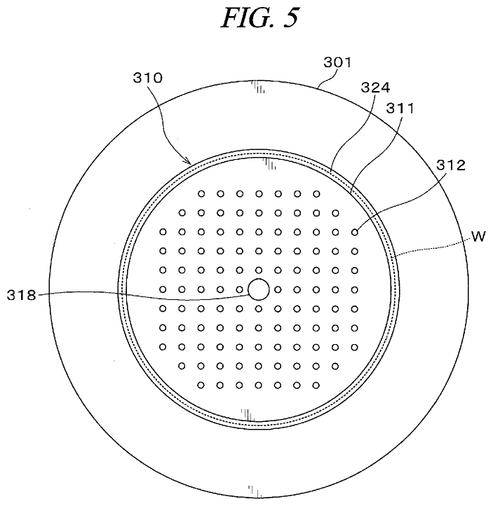

Next, among the heat treatment apparatuses 40, the heat treatment apparatus 40 configured to perform the PEB treatment will be elaborated. FIG. 4 is a longitudinal cross-sectional view illustrating a schematic configuration of the heat treatment apparatus 40 configured to perform the PEB treatment. FIG. 5 is a bottom view schematically illustrating a configuration of an upper chamber 301 to be described later.

The heat treatment apparatus 40 of FIG. 4 is equipped with a chamber 300 forming a processing space K1 in which a heat treatment is performed. The chamber 300 has an upper chamber 301, a lower chamber 302, and a rectifying member 303. The upper chamber 301 is located on the upper side, and the lower chamber 302 is located at the lower side. The rectifying member 303 is located between the upper chamber 301 and the lower chamber 302, and, specifically, it is located between a peripheral portion of the upper chamber 301 and a peripheral portion of the lower chamber 302.

The upper chamber 301 is configured to be movable up and down. An elevating mechanism (not shown), which has a driving source such as a motor and is configured to move the upper chamber 301 up and down, is controlled by the controller 200.

The upper chamber 301 is formed to have, for example, a circular plate shape. The upper chamber 301 has a ceiling portion 310. The ceiling portion 310 forms the processing space K1 therebelow, and is disposed to face the wafer W on a heat plate 328 to be described later. Further, the ceiling portion 310 is provided with a shower head 311 as a “another gas supply” according to the present disclosure.

The shower head 311 is configured to supply a first preset gas from the ceiling portion 310 toward the wafer W on the heat plate 328. The first preset gas supplied by the shower head 311 is, for example, a gas containing moisture, that is, a moisture-containing gas, more specifically, a moisture-containing gas with an adjusted moisture concentration (that is, whose humidity and temperature are adjusted) (hereinafter, sometimes referred to as “temperature/humidity adjusted gas”). For example, the temperature/humidity adjusted gas is generated from the ambient atmosphere around the heat treatment apparatus 40 (specifically, the ambient atmosphere around the coating and developing system) having the same temperature and humidity as those of the ambient atmosphere around the chamber 300. The temperature/humidity adjusted gas as a diluted gas of a high concentration gas to be described later is produced in the same manner, for example.

The shower head 311 is provided with a plurality of discharge holes 312 and a gas distribution space 313.

The discharge holes 312 are formed in a bottom surface of the shower head 311. As illustrated in FIG. 5, for example, the discharge holes 312 are approximately uniformly arranged at a central portion of the bottom surface of the shower head 311 other than where an exhaust opening 318 to be described later is formed. These discharge holes 312 include first discharge holes located above a peripheral portion of the wafer W on the heat plate 328 and second discharge holes located above a central portion of the wafer W on the heat plate 328.

The gas distribution space 313 distributes the temperature/humidity adjusted gas introduced into the shower head 311 into the respective discharge holes 312. As shown in FIG. 4, the shower head 311 is connected via a supply line 314 to a gas source 315 storing the temperature/humidity adjusted gas therein. The supply line 314 is provided with a supply device group 316 including an opening/closing valve configured to control a flow of the temperature/humidity adjusted gas and a flow rate control valve. The supply device group 316 is controlled by the controller 200.

In addition, a central exhaust unit 317 is provided in the ceiling portion 310 of the upper chamber 301. The central exhaust unit 317 and a peripheral exhaust unit 323 to be described later constitute an exhaust unit configured to evacuate the processing space K1.

The central exhaust unit 317 evacuates the processing space K1 above the heat plate 328 within the chamber 300 from a position of the ceiling portion 310 on the center side (from the position of the center in the drawing) when viewed from the top surface of the wafer Won the heat plate 328. The central exhaust unit 317 has the exhaust opening 318. As shown in FIG. 5, the exhaust opening 318 is provided at a position of the bottom surface of the shower head 311 on the center side (the position of the center in the drawing) when viewed from the top surface of the wafer Won the heat plate 328, and is opened downwards. The central exhaust unit 317 evacuates the processing space K1 through this exhaust opening 318.

In addition, although not shown, the exhaust opening 318 may be plural in number, and they may be arranged so as to surround a position corresponding to directly above the center of the wafer W. In this case, in order not to hinder the evacuating operation of the central exhaust unit 317 to be described later, the plurality of exhaust openings 318 are located in an area within, for example, one-third of the radius of the wafer W from the center of the wafer W, when viewed from the top.

As illustrated in FIG. 4, the central exhaust unit 317 has a central exhaust path 319 formed to extend upwards from the exhaust opening 318. The central exhaust path 319 is connected to an exhaust device 321 such as a vacuum pump via an exhaust line 320. The exhaust line 320 is provided with an exhaust device group 322 having a valve configured to adjust an exhaust amount, and so forth. The exhaust device 321 and the exhaust device group 322 are controlled by the controller 200.

In addition, the peripheral exhaust unit 323 is provided in the ceiling portion 310 of the upper chamber 301. The peripheral exhaust unit 323 evacuates the processing space K1 from a position of the ceiling portion 310 on the peripheral side of the wafer W on the heat plate 328 as compared to the central exhaust unit 317, when viewed from the top. The peripheral exhaust unit 323 has an exhaust opening 324. As depicted in FIG. 5, the exhaust opening 324 is opened downwards from the bottom surface of the ceiling portion 310 so as to surround the outer edge of the shower head 311. The exhaust opening 324 may be configured by arranging a plurality of exhaust holes along the outer edge of the shower head 311. The peripheral exhaust unit 323 evacuates the processing space K1 through this exhaust opening 324.

For example, the exhaust opening 324 is provided so that the circumferential edge of the exhaust opening 324 is located between a position overlapping the circumferential edge of the wafer Won the heat plate 328 and a position 10 mm inside that position, when viewed from the top.

The peripheral exhaust unit 323 of FIG. 4 has a peripheral exhaust path extending from the exhaust opening 324. The peripheral exhaust path is connected to an exhaust device 326 such as a vacuum pump via an exhaust line 325. The exhaust line 325 is provided with an exhaust device group 327 having a valve configured to adjust an exhaust amount, and so forth. The exhaust device 326 and the exhaust device group 327 are controlled by the controller 200.

Further, the upper chamber 301 is configured to be heated. By way of example, the upper chamber 301 has therein a heater (not shown) configured to heat the upper chamber 301. This heater is controlled by the controller 200 to adjust the temperature of the upper chamber 301 (as a specific example, the shower head 311) to a predetermined temperature.

The lower chamber 302 is disposed to surround the heat plate 328 (specifically, the side and the bottom of the heat plate 328) that is configured to support and heat the wafer W.

The heat plate 328 has a thick disc shape. The heat plate 328 has, for example, a heater 329 embedded therein. The temperature of the heat plate 328 is adjusted as the heater 329 is controlled by the controller 200, so that the wafer W placed on the heat plate 328 is heated to a predetermined temperature.

In addition, the heat plate 328 has, for example, a plurality of attraction holes 330 through which the wafer W is attracted onto the heat plate 328. Each attraction hole 330 is formed through the heat plate 328 in a thickness direction thereof.

Further, each attraction hole 330 is connected to a relay hole 332 of a relay member 331. Each relay hole 332 is connected to an exhaust line 333 through which evacuation for attraction is performed.

The attraction hole 330 and the relay hole 332 are connected with a metal member 334 and a resin pad 335 therebetween. Specifically, the attraction hole 330 and the relay hole 332 are connected through a path within the metal member 334 and a path within the resin pad 335.

The metal member 334 is located on the attraction hole 330 side, and the resin pad 335 is located on the relay hole 332 side. One end of the metal member 334 is directly connected to the heat plate 328 (specifically, the attraction hole 330), and the other end thereof is directly connected to one end of the corresponding resin pad 335. In other words, each resin pad 335 communicates with the corresponding attraction hole 330 and is connected to the heat plate 328 through the metal member 334. Further, the other end of the resin pad 335 is directly connected to the relay member 331 (specifically, the relay hole 332).

The metal member 334 has a large-diameter portion 336 on the resin pad 335 side. The inside of the large-diameter portion 336 has a flow space 336a having a cross-sectional area larger than that of a portion of the metal member 334 connected to the heat plate 328, so the risk of clogging by a sublimated material generated in the heat treatment is reduced. In addition, this flow space 336a having such a large cross-sectional area relieves heat of a gas sucked from the processing space K1 when the wafer W is attracted, allowing the gas to be flown to the exhaust line 333 for attraction. That is, the risk of degradation of the resin pad 335 and the devices constituting an exhaust flow path leading to the exhaust line 333, which might be caused by high temperature, can be suppressed.

Further, the exhaust line 333 is equipped with an exhaust device (not shown) such as a vacuum pump and an exhaust amount adjusting device group (not shown) having a valve and the like. The exhaust device and the exhaust amount adjusting device group are controlled by the controller 200.

Furthermore, in the lower chamber 302, there are provided, below the heat plate 328, for example, three elevating pins (not shown) configured to support the wafer W from below and move it up and down. The elevating pins are moved up and down by an elevating mechanism (not shown) having a driving source such as a motor or the like. This elevating mechanism is controlled by the controller 200. Further, through holes (not shown) through which the elevating pins pass are formed at the central portion of the heat plate 328. The elevating pins can be protruded from the top surface of the heat plate 328 through the through holes.

In addition, the lower chamber 302 has a support ring 337 and a bottom chamber 338.

The support ring 337 has a cylindrical shape. The support ring 337 is made of, for example, a metal such as stainless steel. The support ring 337 covers the outer side surface of the heat plate 328. The support ring 337 is fixed on the bottom chamber 338.

The bottom chamber 338 has a cylindrical shape with a bottom.

The aforementioned heat plate 328 is supported by, for example, a bottom wall of the bottom chamber 338. Specifically, the heat plate 328 is supported by the bottom wall of the bottom chamber 338 via a support 339. The support 339 includes, by way of example, a supporting column 340 whose upper end is connected to the heat plate 328, an annular member 341 supporting the supporting column 340, and a leg member 342 provided on the bottom wall of the bottom chamber 338 to support the annular member 341.

The annular member 341 is made of a metal, and is provided with a gap as much as the height of the supporting column 340 for most of the rear surface of the heat plate 328. By locating the resin pad 335 under the annular member 341 configured as described above, it is possible to effectively block the heat from the heat plate 328 by the annular member 341, and it becomes difficult for the resin pad 335 to be exposed to the high temperature (difficult for the resin pad 335 to be degraded by the heat).

Moreover, the lower chamber 302 has an inlet 343 through which a second preset gas is introduced into the chamber 300. The inlet 343 is formed in a cylindrical sidewall of the bottom chamber 338, for example.

Further, the inner circumferential surface of the sidewall of the bottom chamber 338 and the inner circumferential surface of the support ring 337 has the same diameter, for example.

The inlet 343 is connected via a supply line 344 to a generating unit 345 configured to generate the second preset gas. The second preset gas is a high concentration gas whose CO₂ concentration is adjusted to be higher than that of the ambient atmosphere around the chamber 300. The CO₂ concentration of the high concentration gas is, for example, 5000 ppm or less. Meanwhile, the CO₂ concentration of the ambient atmosphere around the chamber 300 is in a range of, e.g., 100 ppm to 1000 ppm.

The generating unit 345 has an inlet line 345a through which a CO₂ gas is introduced into the generating unit 345, an inlet line 345b through which a diluted gas is introduced into the generating unit 345, and a tank 345c configured to store the CO₂ gas and diluted gas introduced through the inlet lines 345a and 345b while mixing them into the high concentration gas.

One end of the inlet line 345a is connected to a gas source 345d configured to store therein the CO₂ gas, and the other end thereof is connected to the tank 345c. Likewise, one end of the inlet line 345b is connected to a gas source 345e configured to store therein the diluted gas, and the other end thereof is connected to the tank 345c.

The inlet lines 345a and 345b are equipped with supply device groups 345f and 345g each including a flow rate control valve and an opening/closing valve configured to control the flows of the CO₂ gas and the diluted gas, respectively. The diluted gas is, by way of non-limiting example, a temperature/humidity adjusted gas, or dry air.

The supply device groups 345f and 345g are controlled by the controller 200. For example, the opening degrees of the flow rate control valves of the supply device groups 345f and 345g are adjusted by the controller 200 based on the target CO₂ concentration of the high concentration gas.

In addition, a sensor 345h configured to detect a CO₂ concentration is provided in the tank 345c. A detection result by the sensor 345h is outputted to the controller 200.

The high concentration gas generated by the generating unit 345 is introduced into the chamber 300 via the supply line 344 and the inlet 343. The supply line 344 is provided with an opening/closing valve 346 configured to switch the start and the stop of the supply of the high concentration gas. The opening/closing valve 346 is controlled by the controller 200.

In addition, the heat treatment apparatus 40 has a supply 348. The supply 348 is configured to supply the second preset gas (high concentration gas in the present exemplary embodiment), which is introduced into the chamber 300 through the inlet 343, toward the wafer W on the heat plate 328 from a position at the side of the wafer W on the heat plate 328 and below the processing space K1 (specifically from below the front surface (that is, the top surface) of the wafer W). The supply 348 and the aforementioned shower head 311 constitute a supply mechanism 347 in the present exemplary embodiment. The supply mechanism 347 is a device configured to supply a gas to the processing space K1.

In addition, the supply 348 includes a gas flow path 349 surrounding the side surface of the heat plate 328, and the rectifying member 303.

The gas flow path 349 is formed of, for example, a space between the outer side surface of the heat plate 328 and the inner circumferential surface of the support ring 337. Thus, the gas flow path 349 is formed in, for example, a circular ring shape when viewed from the top. Alternatively, the outer side surface of the heat plate 328 may be supported by the inner circumferential surface of the sidewall of the bottom chamber 302 via a supporting member, and a plurality of through holes may be formed through the supporting member in a vertical direction. In this configuration, the plurality of through holes may be used as the gas flow path 349.

The rectifying member 303 is a member configured to direct the second preset gas that has risen along the gas flow path 349 toward the wafer W on the heat plate 328.

The rectifying member 303 is formed in, for example, a circular ring shape, when viewed from the top.

The inner circumferential bottom surface of the rectifying member 303 serves as a guide surface that leads the second preset gas that has risen along the gas flow path 349 toward the center of the heat plate 328. The inner circumferential edge of the bottom surface of the rectifying member 303 is located at a height equal to or less than a half of the height of the processing space K1, that is, a height from the front surface of the heat plate 328 on which the wafer W is placed up to the bottom surface of the shower head 311 facing the wafer W on the heat plate 328 and provided with the discharge holes 312. For example, the inner circumferential edge of the bottom surface of the rectifying member 303 is located above the front surface of the wafer Won the heat plate 328.

When viewed from the top, the inner circumferential side portion of the rectifying member 303 overlaps with the peripheral portion of the heat plate 328, and does not overlap with the wafer W on the heat plate 328. The second preset gas that has risen along the gas flow path 349 passes through the gap G between the inner circumferential bottom surface of the rectifying member 303 and the top surface of the peripheral portion of the heat plate 328 and heads toward the wafer W on the heat plate 328 from the side of the wafer W within the processing space K1. If the space above the front surface of the heat plate 328 is referred to as the processing space K1, the gap G through which the gas is introduced into the processing space K1 is provided in a lower portion of the processing space K1.

The gap G is connected to one end of the gas flow path 349. Further, the other end of the gas flow path 349 is connected to a buffer space K2 under the heat plate 328 in the chamber 300. The buffer space K2 under the heat plate 328 has a larger volume than the processing space K1 above the heat plate 328.

The inner circumferential surface of the rectifying member 303 is extended linearly from below the ceiling portion 310 of the upper chamber 301.

In one exemplary embodiment, the rectifying member 303 is a solid body. The rectifying member 303 is made of, by way of example, a metal material such as stainless steel.

Further, the entire top surface of the rectifying member 303 is in contact with the bottom surface of the upper chamber 301.

More specifically, the rectifying member 303 is fixed to the upper chamber 301 in such a manner that the entire top surface thereof is in contact with the bottom surface of the upper chamber 301, and is moved up and down along with the upper chamber 301.

As the rectifying member 303 is lowered together with the upper chamber 301 and comes into contact with the lower chamber 302 (specifically, the support ring 337), the chamber 300 is closed. In order to suppress oscillation that might be caused by the contact between the rectifying member 303 and the support ring 337 both of which are made of metals, the following configuration may be adopted. That is, a projection made of a resin may be provided on a surface of the support ring 337 facing the rectifying member 303 so that the rectifying member 303 comes into contact with the projection made of the resin when it is lowered. Further, a projection made of a resin may also be provided on a surface of the rectifying member 303 facing the support ring 337 so that the projection made of the resin comes into contact with the support ring 337 when the rectifying member 303 is lowered. In these cases, it is desirable that the height of the projection made of the resin is as small as possible. This is to reduce a gap between the bottom surface of the rectifying member 303 and the top surface of the support ring 337 to thereby suppress a sublimated material or the like from entering the gap. The height of the projection made of the resin is set to be of a value allowing the gap between the bottom surface of the rectifying member 303 and the top surface of the support ring 337 to be smaller than the shortest distance from the rectifying member 303 to the wafer W on the heat plate 328 at least.

Additionally, the heat treatment apparatus 40 may be further equipped with a cooling plate (not shown) having a function of cooling the wafer W. The cooling plate is reciprocated between, for example, a cooling position outside the chamber 300 and a delivery position where at least a part of the cooling plate is disposed within the chamber 300 and where the wafer W is transferred between the cooling plate and the heat plate 328. Alternatively, the cooling plate may be fixed at a position parallel to the heat plate 328 in a horizontal direction, and the heat treatment apparatus 40 may have a transfer arm configured to transfer the wafer W between the cooling plate and the heat plate 328.

<Wafer Processing Using Heat Treatment Apparatus 40>

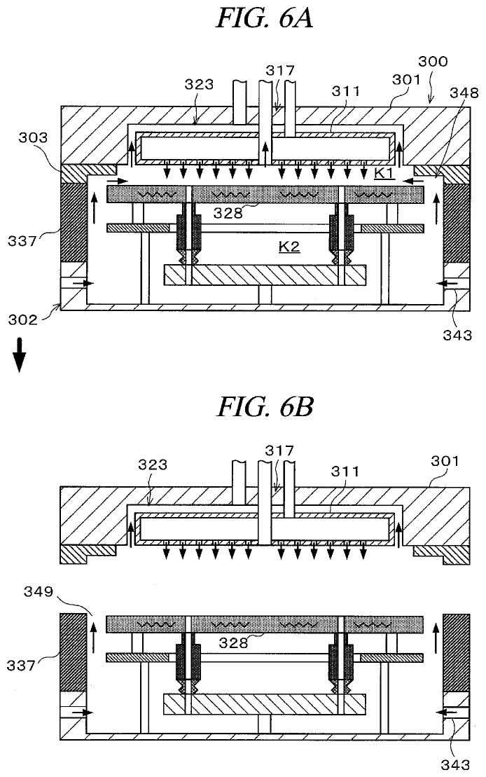

Now, an example of a wafer processing performed by using the heat treatment apparatus 40 will be explained with reference to FIG. 6A to FIG. 11. FIG. 6A to FIG. 8 are diagrams illustrating states of the heat treatment apparatus 40 in the middle of the wafer processing performed by using the heat treatment apparatus 40. FIG. 9 and FIG. 10 are diagrams illustrating line widths of a resist pattern in individual areas of the wafer W, which is obtained by a PEB treatment according to a comparative example to be described later. In FIG. 9 and FIG. 10, an area with a narrower line width is shown to be darker.

Further, the following wafer processing is performed under the control of the controller 200. In the following example, it is assumed that the target CO₂ concentration of the high concentration gas supplied into the chamber 300 is determined in advance according to the type of the metal-containing resist. Further, it is also assumed that the temperature of the temperature/humidity adjusted gas supplied to the shower head 311 and the temperature of the high concentration gas introduced into the chamber 300 through the inlet 343 are set to be a room temperature (25° C.).

(Process S1: Adjustment of Conditions within Chamber)

First, prior to, for example, the placement of the wafer W on the heat plate 328, conditions within the chamber 300 are adjusted.

Specifically, as shown in FIG. 6A, the upper chamber 301 is lowered, so the rectifying member 303 comes into contact with the support ring 337 of the lower chamber 302. That is, in the state that the chamber 300 is closed and the processing space K1 is formed, the heat plate 328 is adjusted to a predetermined temperature.

Further, the humidity and the CO₂ concentration in the processing space K1 are adjusted. The adjustment of the humidity and the CO₂ concentration in the processing space K1 is carried out by continuing, for a predetermined time, the evacuation by the central exhaust unit 317, the evacuation by the peripheral exhaust unit 323, the supply of the temperature/humidity adjusted gas from the shower head 311, and the introduction of the high concentration gas through the inlet 343. In this process, the high concentration gas introduced through the inlet 343 is supplied from the supply 348 into the processing space K1. To be specific, the introduction of the high concentration gas through the inlet 343 is performed by setting the opening/closing valve 346 to be in the open state and by controlling the supply device groups 345f and 345g to have opening degrees according to the target CO₂ concentration of the high concentration gas.

(Process S2: Placement of Wafer)

Then, the wafer W having the metal-containing resist film formed thereon is placed on the heat plate 328.

Specifically, as depicted in FIG. 6B, while carrying on the evacuation by the peripheral exhaust unit 323, the supply of the temperature/humidity adjusted gas from the shower head 311 and the introduction of the high concentration gas through the inlet 343, the evacuation by the central exhaust unit 317 is stopped, and the upper chamber 301 is raised. In this process, the high concentration gas introduced through the inlet 343 is supplied upwards from the gas flow path 349 formed between the outer side surface of the heat plate 328 and the inner circumferential surface of the support ring 337.

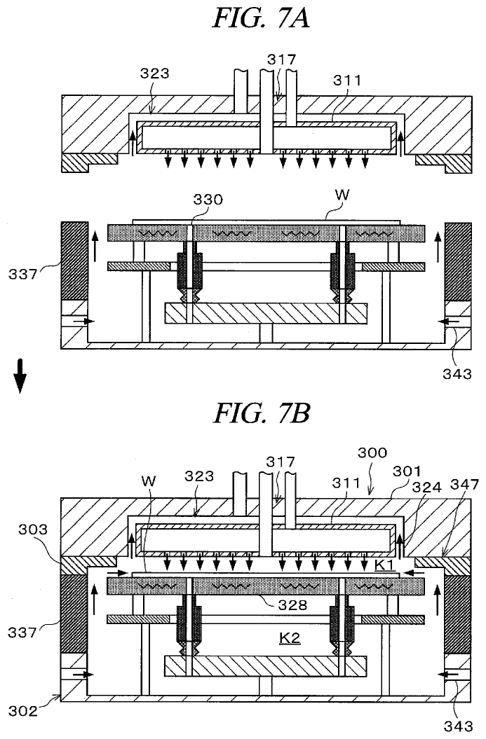

Thereafter, the wafer W is transferred to above the heat plate 328 by the transfer device 70. Subsequently, the elevation of the elevating pins (not shown) or the like is performed, and the delivery of the wafer W from the transfer device 70 to the elevating pins and the delivery of the wafer W from the elevating pins to the heat plate 328 are performed, so that the wafer W is placed on the heat plate 328, as depicted in FIG. 7A. Afterwards, the attraction of the wafer W to the heat plate 328 through the attraction holes 330 is performed.

(Process S3: PEB Treatment)

Subsequently, the wafer Won the heat plate 328 is subjected to the PEB treatment.

(Process S3a: Start of PEB Treatment)

Specifically, as illustrated in FIG. 7B, as the upper chamber 301 is lowered, the rectifying member 303 comes into contact with the support ring 337 of the lower chamber 302, and the chamber 300 is closed, whereby the PEB treatment for the wafer W on the heat plate 328 is begun.

Until a first predetermined time elapses from the start of the PEB treatment, the evacuation by the central exhaust unit 317 is not performed, but the supply of the temperature/humidity adjusted gas from the shower head 311, the evacuation by the peripheral exhaust unit 323, and the introduction of the high concentration gas through the inlet 343 are performed. In this process, the high concentration gas introduced through the inlet 343 is supplied from the supply 348 into the processing space K1. The first predetermined time is set so that solidification of the metal-containing resist film on the wafer W proceeds to a required level. In other words, the first predetermined time is set such that the dehydration condensation of the metal-containing resist on the wafer W proceeds to a required level. Further, the information of the first predetermined time is stored in a storage (not shown).

The high concentration gas introduced into the chamber 300 through the inlet 343 is supplied from the supply 348 into the processing space K1, and is moved to the exhaust opening 324 toward the wafer W, forming an upward flow. As a result, as will be described later, adhesion of a sublimated material to the rear surface and the bevel of the wafer W can be suppressed.

(Process S3b: Start of Central Evacuation)

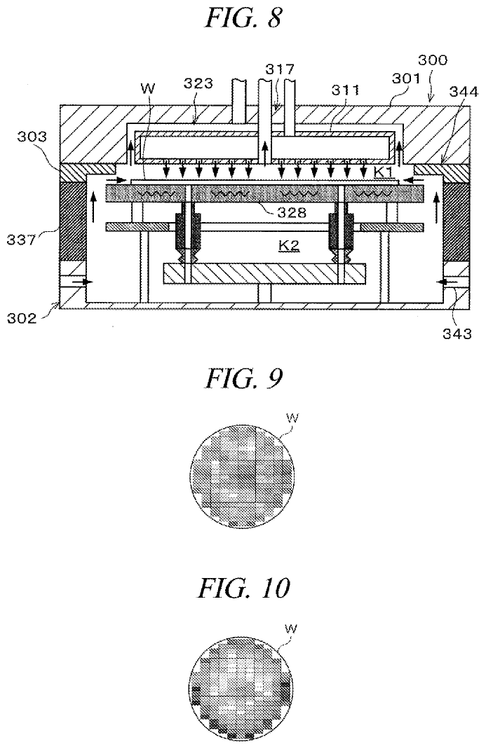

Upon the lapse of the first predetermined time from the start of the PEB treatment, while carrying on the supply of the temperature/humidity adjusted gas from the shower head 311, the evacuation by the peripheral exhaust unit 323, and the introduction of the high concentration gas through the inlet 343, that is, the supply of the high concentration gas from the supply 348 to the processing space K1, the evacuation by the central exhaust unit 317 is started, as illustrated in FIG. 8.

(Process S3c: Stop of PEB Treatment)

When a second predetermined time elapses after the evacuation by the central exhaust unit 317 is started, the PEB treatment is ended. Specifically, the upper chamber 301, for example, is raised, turning the chamber 300 into the open state. At this time, the evacuation by the central exhaust unit 317, the supply of temperature/humidity adjusted gas from the shower head 311, the evacuation by the peripheral exhaust unit 323, and the introduction of the high concentration gas through the inlet 343 are continued.

The second predetermined time is set so that the solidification of the metal-containing resist film on the wafer W proceeds to a required level. The information of the second predetermined time is stored in the storage (not shown).

The first predetermined time and the second predetermined time are set as follows. That is, the first predetermined time and the second predetermined time are set such that a ratio of a period during which the evacuation by the central exhaust unit 317 is performed is set to be 1/20 to ½ of a total time of the PEB treatment. More specifically, when the total time of the PEB treatment is 60 seconds, the period during which the evacuation by the central exhaust unit 317 is performed is set to be 3 seconds to 30 seconds. The total time of the PEB treatment refers to, for example, a time from when the wafer W is placed on the heat plate 328 and the upper chamber 301 is lowered to close the chamber 300 to when the upper chamber 301 is raised to open the chamber 300.

The present inventors have conducted a test in an example (hereinafter, referred to as a comparative example) in which the ambient atmosphere around the chamber 300 is introduced into the chamber 300 through the inlet 343 to be supplied into the processing space K1 during the PEB treatment, unlike in the present exemplary embodiment. For each of two cases in which sizes of line widths of a resist pattern obtained through the developing processing or the like after the PEB treatment are different, the values of the line widths as a result of performing the test under a plurality of conditions where the CO₂ concentration is varied within the range of 100 ppm to 1000 ppm while the other parameters are not particularly changed. As a result of the test, line width variations of about 3% and about 4% are observed in the two cases where the sizes of the line widths are different, respectively, and the line widths are found to be different depending on the CO₂ gas concentration in the ambient atmosphere. To elaborate, the lower the CO₂ gas concentration of the ambient atmosphere, the narrower the line width, which is equally observed in the two cases in which the sizes of the line widths are different. As for the reason why the line width of the resist pattern is narrowed when the CO₂ gas concentration is low, it is assumed that if the CO₂ gas concentration is low, the CO₂ gas reacting with the metal-containing resist is insufficient, so that the amount of hydrolysis becomes insufficient, which in turn results in an insufficient amount of dehydration condensation, that is, an insufficient degree of the solidification.

Meanwhile, in the present exemplary embodiment, the high concentration gas having the higher CO₂ concentration than the ambient atmosphere around the chamber 300 is introduced into the chamber 300 through the inlet 343 to be supplied into the processing space K1 during the PEB treatment. For this reason, during the PEB treatment, the CO₂ concentration in the chamber 300 (specifically, the CO₂ concentration in the processing space K1) can be made substantially constant at the high value regardless of the CO₂ concentration in the ambient atmosphere around the chamber 300. Accordingly, the line width of the resist pattern can be stabilized regardless of the CO₂ concentration in the ambient atmosphere around the chamber 300.

Further, in the comparative example, when the CO₂ concentration of the ambient atmosphere around the chamber 300 is high, the line width of the resist pattern is substantially uniform within the surface of the wafer W, as shown in FIG. 9. However, when the CO₂ concentration of the ambient atmosphere around the chamber 300 is low, the line width of the resist pattern is found to be non-uniform within the surface of the wafer W, as shown in FIG. 10. To be specific, the line width of the resist pattern at the peripheral portion of the wafer W is found to be narrower than the line widths at the other portions. The reason for this is assumed as follows. That is, in the process S3a, since the upward flow heading toward the exhaust opening 324 is formed near the periphery of the wafer W, the CO₂ concentration at the periphery of the wafer W tends to be lower than that at the center of the wafer W. However, when the CO₂ gas concentration in the ambient atmosphere around the chamber 300 is high, the atmosphere with the high CO₂ gas concentration is supplied from the supply 348 to the periphery of the wafer W via the inlet 343. Therefore, even at the periphery of the wafer W, the CO₂ concentration becomes sufficient. However, when the CO₂ concentration of the ambient atmosphere around the chamber 300 is low, since the CO₂ concentration of the gas supplied from the supply 348 to the periphery of the wafer W is also low, the CO₂ concentration at the periphery of the wafer W becomes low. As a result, the solidification of the metal-containing resist becomes insufficient, causing the line width to be narrowed. This is deemed to be the reason.

In contrast, in the present exemplary embodiment, the gas supplied from the supply 348 to the periphery of the wafer W is the high concentration gas with the high CO₂ concentration. Accordingly, the CO₂ concentration at the periphery of the wafer W can be made sufficiently high. Therefore, the line width of the resist pattern can be made uniform within the surface of the wafer W regardless of the CO₂ concentration of the ambient atmosphere around the chamber 300.

The present inventors have observed that the CO₂ concentration of the gas exhausted from the chamber 300 temporarily rises during the PEB treatment according to the comparative example. That is, the present inventors have confirmed that the CO₂ gas is generated from the metal-containing resist film during the PEB treatment according to the comparative example. It is assumed that the CO₂ gas generated from the metal-containing resist film during the PEB treatment also contributes to the solidification of the metal-containing resist, and it is also assumed that the generated CO₂ gas is mainly consumed at the central portion of the wafer W. Therefore, the target CO₂ concentration of the high concentration gas introduced into the chamber 300 through the inlet 343 may be set to satisfy the following expression (1) so that the CO₂ concentration becomes uniform within the surface of the wafer W.

D1+D2=D3 (1)
D1: a CO₂ concentration by the gas supplied from the shower head 311
D2: a CO₂ concentration by the gas generated from the metal-containing resist film
D3: a CO₂ concentration of the high concentration gas introduced into the chamber 300
   through the inlet 343

In addition, the aforementioned CO₂ concentration D3 may be set to satisfy the following expression (2) by considering a CO₂ concentration D4 of the ambient atmosphere around the chamber 300 that is introduced into the processing space K1 from between the rectifying member 303 and the support ring 337.

D1+D2=D3+D4 (2)

Further, when the CO₂ concentration of the high concentration gas detected by the sensor 345h in the tank 345c is not within the predetermined range, the controller 200 may perform a control so that an alarm is outputted through an output device such as a display or a speaker.

Moreover, the flow rate of the high concentration gas introduced into the chamber 300 through the inlet 343 is maintained constant during the PEB treatment, for example.

In addition, in the case of performing the evacuation only by the peripheral exhaust unit 323 without performing the evacuation by the central exhaust unit 317 as in the process S3a, a flow of the temperature/humidity adjusted gas moving to the peripheral portion of the wafer W in the radial direction is formed near the front surface of the wafer W along the front surface of the wafer W.

On the other hand, when performing the evacuation by the central exhaust unit 317 as well as in the process S3b, the gas does not flow along the front surface of the wafer W but flows so as to rise as it goes from the periphery on the wafer W toward the center. For this reason, the distance between a boundary layer of the airflow of the gas directed to the central exhaust unit 317 and the front surface of the wafer W becomes non-uniform within the surface of the wafer W. This causes non-uniformity in a volatilization amount from the metal-containing resist film on the wafer W. This non-uniformity of the volatilization amount adversely affects in-surface uniformity of the film thickness on the wafer W at the beginning of the PEB treatment, when the solidification is not progressing so the volatilization amount is large.

Therefore, in the process S3a, from the start of the PEB treatment until the first predetermined time elapses, the evacuation by the central exhaust unit 317 is not performed, and the supply of the temperature/humidity adjusted gas from the shower head 311 and the evacuation by the peripheral exhaust unit 323 are performed.

Further, in the process S3a, since the high concentration gas is introduced through the inlet 343 and this high concentration gas is supplied into the processing space K1 from the supply 348, the gas heading toward the wafer W from the supply 348 moves to the exhaust opening 324, forming the upward flow near the wafer W. At this time, the temperature/humidity adjusted gas, which may contain the sublimated material and is discharged from the shower head 311 toward the wafer W and moved along the front surface of the wafer W, also moves upwards along with the upward flow to be exhausted to the outside through the exhaust opening 324. Therefore, the sublimated material can be suppressed from adhering to the rear surface and the bevel of the wafer W.

In the process S3b, by performing the evacuation by the central exhaust unit 317, the flow of the temperature/humidity adjusted gas heading toward the central portion of the wafer W from the peripheral side thereof is formed near the front surface of the wafer W. For this reason, the temperature/humidity adjusted gas that may contain the sublimated material near the front surface of the wafer W is exhausted through the central exhaust unit 317 as well. Further, the exhaust amount by the central exhaust unit 317 may be set to be larger than the exhaust amount by the peripheral exhaust unit 323. In this case, the temperature/humidity adjusted gas, which may contain the sublimated material near the front surface of the wafer W, is exhausted mainly through the central exhaust unit 317. Therefore, the adhesion of the sublimated material to the rear surface and the bevel of the wafer W can be further suppressed. In addition, in this stage of performing the evacuation by the central exhaust unit 317, the solidification of the metal-containing resist film has already progressed. Thus, the influence of the airflow accompanied by the exhausting operation on the film thickness variation is small. For this reason, even if the evacuation by the central exhaust unit 317 is performed, its effect on the in-surface uniformity of the film thickness is small.

Additionally, during the PEB treatment, the upper chamber 301 is heated. This is to suppress the sublimated material from being re-solidified and attached to the upper chamber 301. During the PEB treatment, the temperature/humidity adjusted gas supplied from the shower head 311 is heated by the heated upper chamber 301. Meanwhile, the high concentration gas supplied from the supply 348 toward the wafer W on the heat plate 328 during the PEB treatment is the gas introduced into the chamber 300 through the inlet 343, which is then heated by the heat plate 328 in the buffer space K2 or heated by this heated gas. During the PEB treatment, the high concentration gas supplied from the supply 348 toward the wafer W on the heat plate 328 is also heated by the rectifying member 303 which is heated by the upper chamber 301.

(Process S4: Carry-Out of Wafer)

Upon the completion of the process S3, the wafer W is removed from the heat plate 328 and carried out of the heat treatment apparatus 40 in the reverse order to that in case of placing the wafer W.

<Main Effects of Present Exemplary Embodiment>

As described above, according to the present exemplary embodiment, the line width of the resist pattern can be made uniform within the surface of the wafer W regardless of the CO₂ concentration in the ambient atmosphere around the chamber 300. That is, according to the present exemplary embodiment, the result of the heat treatment on the wafer W on which the metal-containing resist film is formed can be stabilized.

Further, in the present exemplary embodiment, the gas supplied from below the front surface of the wafer on the heat plate 328 toward the wafer Won the heat plate 328 by the supply 348 is the gas heated by the heat plate 328 within the buffer space K2, or the gas heated by this heated gas. Also, the buffer space K2 has the larger volume than the processing space K1. For this reason, the supply of the heated gas into the processing space K1 can be performed for a maximum period of time. When an unheated gas is supplied to the processing space K1, this gas may cool the members (for example, the upper chamber 301) around the processing space K1, resulting in the solidification of the sublimated material. In the present exemplary embodiment, since the supply of the heated gas to the processing space K1 can be performed for the maximum period of time, such solidification of the sublimated material can be suppressed. Furthermore, if the unheated gas is supplied from the supply 348 toward the wafer W, there is a risk that the heat treatment of the peripheral portion of the wafer W may be affected. In contrast, in the present exemplary embodiment, since the gas supplied from the supply 348 toward the wafer W is heated, the deterioration of the in-surface uniformity of the heat treatment due to the gas can be suppressed. Meanwhile, since the volume of the processing space K1 is small, the heat capacity of the gas inside the processing space K1 is also reduced. Therefore, when the heated gas is supplied to the processing space K1 for the long time, the temperature of the processing space K1 may also be easily stabilized.

Moreover, in the present exemplary embodiment, the upper chamber 301 is configured to be heated. Further, the entire top surface of the rectifying member 303 is in contact with the bottom surface of the upper chamber 301. For this reason, by heating the upper chamber 301, the rectifying member 303 can be heated efficiently. Furthermore, the rectifying member 303 is the solid body and has the large heat capacity. For this reason, by heating the rectifying member 303, the gas supplied from the supply 348 can be efficiently heated by the rectifying member 303. Therefore, according to the present exemplary embodiment, the gas supplied from the supply 348 can be heated by the heated upper chamber 301. Hence, it is possible to suppress the aforementioned solidification of the sublimated material and the deterioration of the in-surface uniformity of the heat treatment that might be caused by the gas supplied from the supply 348.

Further, in the present exemplary embodiment, the rectifying member 303 is moved up and down together with the upper chamber 301. For this reason, the rectifying member 303 is heated by the upper chamber 301 regardless of the position of the upper chamber 301. That is, in order to place the wafer W on the heat plate 328, even if the upper chamber 301 is raised and the chamber 300 is left open, the rectifying member 303 is held by the upper chamber 301. As a result, the rectifying member 303 can be maintained at the high temperature. Therefore, according to the present exemplary embodiment, the gas supplied from the supply 348 can be heated by the rectifying member 303 even immediately after the chamber 300 is closed. Therefore, it is possible to suppress the above-described solidification of the sublimated material and deterioration of the in-surface uniformity of the heat treatment caused by the gas supplied from the supply 348.

Furthermore, in the present exemplary embodiment, the inner circumferential surface of the rectifying member 303 is linearly extended downwards from the ceiling portion 310 of the upper chamber 301. That is, on the inner circumferential side of the rectifying member 303, no recessed portion that is recessed outwards exists above the bottom surface of the inner circumferential side, that is, the guide surface. When such a recessed portion is present, a gas that may contain a sublimated material may stay in this recessed portion, causing particles. In the present exemplary embodiment, however, since the recessed portion as described above does not exist, the generation of the particles can be suppressed.

In addition, the shape of the inner circumferential surface of the rectifying member 303 that is extended downwards from the ceiling 310 of the upper chamber 301 does not have to be a perfect straight line shape. In other words, the inner circumferential surface of the rectifying member 303 may be slightly recessed outwards within the range in which retention of the gas does not occur. By way of example, in order to suppress breakage of an upper end corner portion of the inner circumferential surface of the rectifying member 303, the upper end corner portion may be chamfered, and, as a result, the inner circumferential surface of the rectifying member 303 may be recessed outwards. The recessed portion formed by the chamfering for the suppression of the breakage of the corner portion is sufficiently small, so that the retention of the gas does not occur, and, even if it does occur, the effect is small.

Furthermore, in the present exemplary embodiment, the resin pad 335 communicates with the attraction hole 330 via the metal member 334 and is connected to the heat plate 328. Thus, according to the present exemplary embodiment, the deterioration of the resin pad 335 due to the heat from the heat plate 328 can be suppressed, as compared to the case where the resin pad 335 is directly connected to the heat plate 328.

In addition, as described above, the opening degrees of the flow rate control valves of the supply device groups 345f and 345g are adjusted based on the target CO₂ concentration of the high concentration gas introduced through the inlet 343. This opening degree may be fixed, or may be adjusted based on the detection result of the sensor 345h in the tank 345c so as to obtain the target CO₂ concentration. Further, a sensor configured to detect the CO₂ concentration in the processing space K1 may be provided in the chamber 300, and the opening degrees of the flow rate control valves of the supply device groups 345f and 345g may be adjusted based on a detection result of this sensor. Specifically, the opening degrees of the flow rate control valves of the supply device groups 345f and 345g may be adjusted so that the detection result by the sensor configured to detect the CO₂ concentration in the processing space K1 becomes the target value.

### Second Exemplary Embodiment

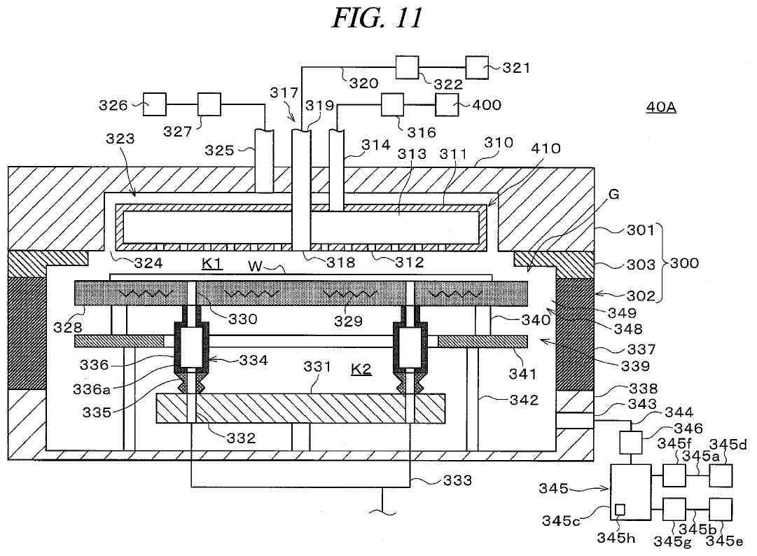

FIG. 11 is a longitudinal cross-sectional view schematically illustrating an outline of a configuration of a heat treatment apparatus according to a second exemplary embodiment.

In the heat treatment apparatus 40 of FIG. 4, the gas source 315 storing therein the temperature/humidity adjusted gas as the first preset gas is connected to the shower head 311 via the supply line 314. Also, in the heat treatment apparatus 40 of FIG. 4, the supply mechanism 347 configured to supply the gas to the processing space K1 supplies, only from the supply 348, the high concentration gas whose CO₂ concentration is adjusted to be higher than that of the ambient atmosphere around the chamber 300.

On the other hand, in a heat treatment apparatus 40A of FIG. 11, a gas source 400 storing therein the high concentration gas as the first preset gas is connected to the shower head 311 via the supply line 314. In the heat treatment apparatus 40A of FIG. 11, a supply mechanism 410 configured to supply a gas to the processing space K1 supplies the high concentration gas toward the wafer W on the heat plate 328 from both the supply 348 and the shower head 311. That is, in the heat treatment apparatus 40A, the supply mechanism 410 supplies the high concentration gas toward the wafer Won the heat plate 328 from the position at the side of the wafer W on the heat plate 328 and below the processing space K1 and from the ceiling portion 310.

Further, the gas source 400 is configured in the same way as the generating unit 345, for example.

In the present exemplary embodiment, the CO₂ concentration of the high concentration gas supplied to the shower head 311 to make the CO₂ concentration uniform within the surface of the wafer W is set as follows, for example. That is, by taking the CO₂ gas generated from the metal-containing resist film during the heat treatment into consideration, the CO₂ concentration is set to be smaller than that of the high concentration gas that is introduced into the chamber 300 through the inlet 343 and supplied to the periphery of the wafer W from the supply 348.

In addition, the aforementioned CO₂ concentration may be set to be equal to that of the high concentration gas that is introduced into the chamber 300 through the inlet 343 and supplied from the supply 348 to the periphery of the wafer W.

According to the second exemplary embodiment, the CO₂ concentration in the chamber 300 (specifically, the CO₂ concentration in the processing space K1) can be maintained substantially constant at a high value regardless of the CO₂ concentration in the ambient atmosphere around the chamber 300, the same as in the first exemplary embodiment. Therefore, regardless of the CO₂ concentration of the ambient atmosphere around the chamber 300, the line width of the resist pattern can be stabilized.

Also, according to the present exemplary embodiment, the CO₂ concentration at the periphery of the wafer W during the heat treatment can be set to be sufficiently high, the same as in the first exemplary embodiment. Therefore, the line width of the resist pattern can be made uniform within the surface of the wafer W regardless of the CO₂ concentration of the ambient atmosphere around the chamber 300.

The present exemplary embodiment is useful when the degree of deterioration of the roughness of the resist pattern is small even when the CO₂ amount is excessive, for example.

### Third Exemplary Embodiment

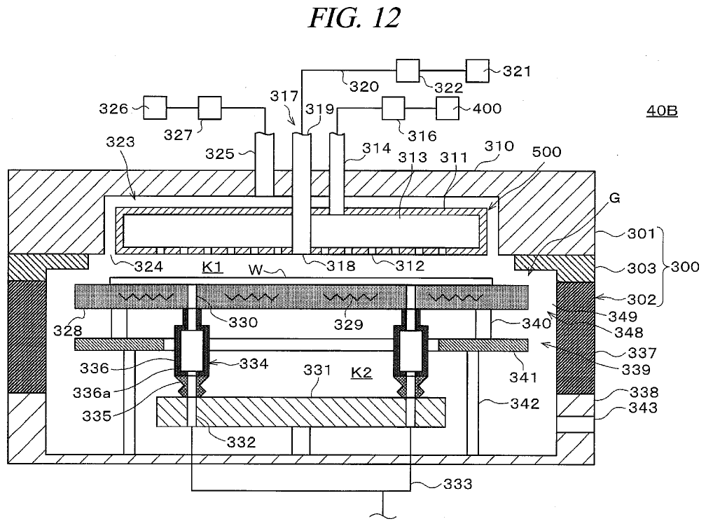

FIG. 12 is a longitudinal cross-sectional view schematically illustrating an outline of a configuration of a heat treatment apparatus according to a third exemplary embodiment.

In the heat treatment apparatus 40 of FIG. 4, the high concentration gas is supplied only from the supply 348, and in the heat treatment apparatus 40A of FIG. 11, the high concentration gas is supplied from both the supply 348 and the shower head 311. Meanwhile, in a heat treatment apparatus 40B of FIG. 12, a supply mechanism 500 configured to supply a gas to the processing space K1 supplies the high concentration gas toward the wafer W on the heat plate 328 from only the shower head 311. That is, in the heat treatment apparatus 40B, the supply mechanism 500 supplies the high concentration gas toward the wafer W on the heat plate 328 from only the ceiling portion 310. From the supply 348 of the heat treatment apparatus 40B, the ambient atmosphere of the chamber 300 introduced into the chamber 300 via the inlet 343 is supplied.

According to the third exemplary embodiment, the CO₂ concentration in the chamber 300 (specifically, the CO₂ concentration in the processing space K1) can be maintained substantially constant at a high value regardless of the CO₂ concentration of the ambient atmosphere around the chamber 300, the same as in the first exemplary embodiment and so forth. Therefore, regardless of the CO₂ concentration of the ambient atmosphere of the chamber 300, the line width of the resist pattern can be stabilized.

Although different from that shown in the drawing, in the present exemplary embodiment, the plurality of discharge holes 312 of the shower head 311 may be formed even in an area outside the wafer W on the heat plate 328 when viewed from the top. Accordingly, as in the first exemplary embodiment, the CO₂ concentration at the periphery of the wafer W during the heat treatment can be set to be sufficiently high. Therefore, the line width of the resist pattern can be made uniform within the surface of the wafer W regardless of the CO₂ concentration of the ambient atmosphere of the chamber 300.

### Modification Examples

During the heat treatment (specifically, during the PEB treatment), the flow rate of the high concentration gas supplied from the supply mechanism 347 (410 or 500) is constant, for example. However, the flow rate may be reduced from the middle of the heat treatment (specifically, the PEB treatment). More specifically, the second preset gas to be introduced into the chamber 300 through the inlet 343 and supplied from the supply 348 may be switched from the high concentration gas to the ambient atmosphere of the chamber 300 during the PEB treatment, or the first preset gas to be supplied to the shower head 311 may be switched from the high concentration gas to the temperature/humidity adjusted gas during the PEB treatment.

The timing for reducing the flow rate of the high concentration gas is, for example, the time when the process S3b is started, that is, the time when the evacuation by the central exhaust unit 317 is turned on.

Further, by reducing the flow rate of the high concentration gas supplied from the supply mechanism 347 (410 or 500) from the middle of the heat treatment, a leak of the CO₂ gas can be suppressed when the chamber 300 is opened after the PEB treatment, so that safety can be improved.

In the above-described exemplary embodiments, the evacuation by the central exhaust unit 317 is performed starting from the middle of the PEB treatment so that the evacuation by the central exhaust unit 317 is not performed at the beginning of the PEB treatment. Instead of this, however, the evacuation by the central exhaust unit 317 may be weakly performed at the beginning of the PEB treatment, and, then, from the middle of the PEB treatment, the evacuation by the central exhaust unit 317 may be enhanced.

Further, during a period in which the evacuation by the central exhaust unit 317 is performed from the middle of the PEB treatment or a period in which the evacuation by the central exhaust unit 317 is enhanced (hereafter, referred to as central evacuation enhancement period), the controller 200 may perform a control so that the supply flow rate of the gas to the gas distribution space 313 of the shower head 311 increases. The reason for this is as follows.

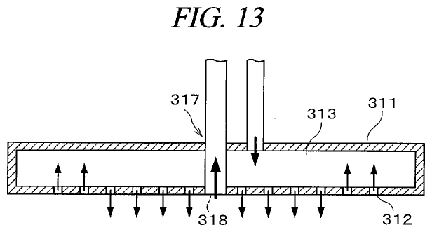

The gas distribution space 313 is shared by the discharge holes 312 on the peripheral side and the discharge holes 312 on the center side. Also, in the central evacuation enhancement period, a discharge flow rate of the gas from the discharge holes 312 on the center side close to the central exhaust unit 317 (specifically, the exhaust opening 318) increases. Accordingly, in the central evacuation enhancement period, depending on the level of the evacuation by the central exhaust unit 317, the discharge of the gas from the discharge holes 312 on the peripheral side into the processing space K1 may not be performed, and, to the contrary, the gas may be sucked from the processing space K1 through the discharge holes 312 on the peripheral side, as illustrated in FIG. 13. In the central evacuation enhancement period, by increasing the supply flow rate of the gas to the gas distribution space 313 of the shower head 311, the sucking of the gas from the processing space K1 through the discharge holes 312 on the peripheral side, that is, a backflow of the gas into the shower head 311 can be suppressed.

As another example, for the plurality of heat treatment apparatuses 40, both the heat treatment apparatus according to the present disclosure and a heat treatment apparatus which is configured to supply a gas of a different type or a different concentration into the processing space or which has a different pressure condition may be adopted. By way of example, when the heat treatments are performed on the exposed wafer W multiple times, it may be possible to use the heat treatment apparatus according to the present disclosure and the heat treatment apparatus with the different gas type, the different gas concentration or the different pressure condition while switching them for each of the multiple times depending on the purposes. That is, multiple heat treatments with different component types, different component concentrations or different pressure conditions in the processing space are performed on the exposed wafer W.

The above description has been provided for the example where the technique according to the present disclosure is applied to the heat treatment apparatus 40 configured to perform the PEB treatment. However, the technique according to the present disclosure may also be applicable to the heat treatment apparatus 40 configured to perform the PAB treatment or the heat treatment apparatus 40 configured to perform the POST treatment.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

In addition, the following configuration examples are also included in the technical scope of the present disclosure.
(1) A heat treatment apparatus configured to heat-treat a substrate having a metal-containing resist film formed thereon, the heat treatment apparatus comprising:
a heat plate configured to support and heat the substrate;
a chamber in which the heat plate is accommodated and a processing space in which a heat treatment is performed is formed;
an exhaust unit configured to evacuate an inside of the processing space; and
a supply mechanism configured to supply a gas into the processing space,
wherein the supply mechanism supplies, into the processing space, a high concentration gas whose CO₂ concentration is adjusted to be higher than that of an ambient atmosphere around the chamber.

(2) The heat treatment apparatus as described in (1),
wherein the supply mechanism supplies the high concentration gas toward the substrate on the heat plate from a position at a side of the substrate on the heat plate and below the processing space, and supplies a moisture-containing gas toward the substrate on the heat plate from a ceiling portion of the chamber.

(3) The heat treatment apparatus as described in (1),
wherein the supply mechanism supplies the high concentration gas toward the substrate on the heat plate from a position at a side of the substrate on the heat plate and below the processing space and from a ceiling portion of the chamber.

(4) The heat treatment apparatus as described in (1),
wherein the supply mechanism supplies the high concentration gas toward the substrate on the heat plate from a ceiling portion of the chamber, and supplies a moisture-containing gas toward the substrate on the heat plate from a position at a side of the substrate on the heat plate and below the processing space.

(5) The heat treatment apparatus as described in any one of (1) to (4), further comprising:
a controller,
wherein the controller performs a control such that a flow rate of the high concentration gas supplied from the supply mechanism is reduced from a middle of the heat treatment.

(6) The heat treatment apparatus as described in any one of (1) to (5), further comprising:
a generating unit configured to generate the high concentration gas.

(7) The heat treatment apparatus as described in any one of (1) to (6),
wherein the supply mechanism has a supply configured to supply the gas toward the substrate on the heat plate from a position at a side of the substrate on the heat plate and below the processing space, and
wherein the supply comprises:
a gas flow path provided to surround a side surface of the heat plate; and
a rectifying member configured to direct the gas that has risen along the gas flow path toward the substrate on the heat plate.

(8) The heat treatment apparatus as described in (7),
wherein the gas flow path is connected to a buffer space below the heat plate in the chamber, and
the buffer space has a volume larger than that of the processing space.

(9) The heat treatment apparatus as described in (7) or (8),
wherein the chamber comprises an upper chamber, including a ceiling portion of the chamber, configured to be moved up and down,
the upper chamber is configured to be heated, and
the rectifying member is a solid body, and an entire top surface thereof is in contact with a bottom surface of the upper chamber.

(10) The heat treatment apparatus as described in (7) or (8),
wherein the chamber comprises an upper chamber, including a ceiling portion of the chamber, configured to be moved up and down,
the upper chamber is configured to be heated, and
the rectifying member is a solid body, and is fixed to the upper chamber in such a manner that an entire top surface thereof is in contact with a bottom surface of the upper chamber so that the rectifying member is moved up and down along with the upper chamber.

(11) The heat treatment apparatus as described in any one of (1) to (10),
wherein the heat plate has an attraction hole configured to attract the substrate to the heat plate,
the heat treatment apparatus further comprises a resin pad having a flow path communicating with the attraction hole, and
the resin pad communicates with the attraction hole, and is connected to the heat plate via a metal member.

(12) The heat treatment apparatus as described in (11),
wherein the metal member has a large-diameter portion.

(13) The heat treatment apparatus as described in (11) or (12), further comprising:
an annular member connected to a lower portion of the heat plate with a supporting column therebetween, and
wherein the resin pad is located under the annular member.

(14) The heat treatment apparatus as described in any one of (1) to (13), further comprising:
a central exhaust unit configured to evacuate the inside of the processing space from a position of a ceiling portion of the chamber on a center side of the substrate on the heat plate, when viewed from above;
a peripheral exhaust unit configured to evacuate the inside of the processing space from a position of the ceiling portion on a peripheral side of the substrate on the heat plate as compared to the central exhaust unit, when viewed from above; and
a controller,
wherein the supply mechanism comprises another gas supply provided at the ceiling portion and configured to supply a gas toward the substrate on the heat plate,
wherein the another gas supply comprises:
a first discharge hole located above a peripheral portion of the substrate on the heat plate;
a second discharge hole located above a central portion of the substrate on the heat plate; and
a gas distribution space in which the gas introduced into the another gas supply is distributed into the first discharge hole and the second discharge hole, and
wherein the controller performs a control such that, during the heat treatment, a supply from the another gas supply and an evacuation by the peripheral exhaust unit are carried on and an evacuation by the central exhaust unit is enhanced from a middle of the heat treatment, and performs a control such that a flow rate of the gas supplied to the gas distribution space is increased in a period during which the evacuation by the central exhaust unit is enhanced.

(15) A heat treatment method of heat-treating a substrate having a metal-containing resist film formed thereon, the heat treatment method comprising:
placing the substrate on a heat plate configured to support and heat the substrate; and
heat-treating the substrate on the heat plate,
wherein the heat-treating of the substrate comprises:
evacuating a processing space in which a heat treatment is performed; and
supplying a gas to the processing space, and
wherein, in the supplying of the gas, a high concentration gas, whose CO₂ concentration is adjusted to be higher than that of an ambient atmosphere around a chamber in which the processing space is formed, is supplied to the processing space.

(16) The heat treatment method as described in (15),
wherein, in the supplying of the gas, the high concentration gas is supplied toward the substrate on the heat plate from a position at a side of the substrate on the heat plate and below the processing space, and a moisture-containing gas is supplied toward the substrate on the heat plate from a ceiling portion of the chamber.

(17) The heat treatment method as described in (15),
wherein, in the supplying of the gas, the high concentration gas is supplied toward the substrate on the heat plate from a position at a side of the substrate on the heat plate and below the processing space and from a ceiling portion of the chamber.

(18) The heat treatment method as described in (15),
wherein, in the supplying of the gas, the high concentration gas is supplied toward the substrate on the heat plate from a ceiling portion of the chamber, and a moisture-containing gas is supplied toward the substrate on the heat plate from a position at a side of the substrate on the heat plate and below the processing space.

(19) The heat treatment method as described in any one of (15) to (18),
wherein, in the supplying of the gas, a flow rate of the high concentration gas is reduced from a middle of the heat treatment.

(20) A computer-readable recording medium having stored thereon computer-executable instructions that, in response to execution, cause a heat treatment apparatus to perform a heat treatment method as described in any one of (15) to (19).

According to the present disclosure, it is possible to provide the technique capable of stabilizing the result of the heat treatment on the substrate on which the metal-containing resist film is formed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A heat treatment apparatus configured to heat-treat a substrate having a metal-containing resist film formed thereon, the heat treatment apparatus comprising:
a heat plate configured to support and heat the substrate;
a chamber in which the heat plate is accommodated and a processing space in which a heat treatment is performed is formed;
an exhaust unit configured to evacuate an inside of the processing space; and
a supply mechanism configured to supply a gas into the processing space,
wherein the supply mechanism supplies, into the processing space, a high concentration gas whose CO₂ concentration is adjusted to be higher than that of an ambient atmosphere around the chamber.

2. The heat treatment apparatus of claim 1,
wherein the supply mechanism supplies the high concentration gas toward the substrate on the heat plate from a position at a side of the substrate on the heat plate and below the processing space, and supplies a moisture-containing gas toward the substrate on the heat plate from a ceiling portion of the chamber.

3. The heat treatment apparatus of claim 1,
wherein the supply mechanism supplies the high concentration gas toward the substrate on the heat plate from a position at a side of the substrate on the heat plate and below the processing space and from a ceiling portion of the chamber.

4. The heat treatment apparatus of claim 1,
wherein the supply mechanism supplies the high concentration gas toward the substrate on the heat plate from a ceiling portion of the chamber, and supplies a moisture-containing gas toward the substrate on the heat plate from a position at a side of the substrate on the heat plate and below the processing space.

5. The heat treatment apparatus of claim 1, further comprising:
a controller,
wherein the controller performs a control such that a flow rate of the high concentration gas supplied from the supply mechanism is reduced from a middle of the heat treatment.

6. The heat treatment apparatus of claim 1, further comprising:
a generating unit configured to generate the high concentration gas.

7. The heat treatment apparatus of claim 1,
wherein the supply mechanism has a supply configured to supply the gas toward the substrate on the heat plate from a position at a side of the substrate on the heat plate and below the processing space, and
wherein the supply comprises:
a gas flow path provided to surround a side surface of the heat plate; and
a rectifying member configured to direct the gas that has risen along the gas flow path toward the substrate on the heat plate.

8. The heat treatment apparatus of claim 7,
wherein the gas flow path is connected to a buffer space below the heat plate in the chamber, and
the buffer space has a volume larger than that of the processing space.

9. The heat treatment apparatus of claim 7,
wherein the chamber comprises an upper chamber, including a ceiling portion of the chamber, configured to be moved up and down,
the upper chamber is configured to be heated, and
the rectifying member is a solid body, and an entire top surface thereof is in contact with a bottom surface of the upper chamber.

10. The heat treatment apparatus of claim 7,
wherein the chamber comprises an upper chamber, including a ceiling portion of the chamber, configured to be moved up and down,
the upper chamber is configured to be heated, and
the rectifying member is a solid body, and is fixed to the upper chamber in such a manner that an entire top surface thereof is in contact with a bottom surface of the upper chamber so that the rectifying member is moved up and down along with the upper chamber.

11. The heat treatment apparatus of claim 1,
wherein the heat plate has an attraction hole configured to attract the substrate to the heat plate,
the heat treatment apparatus further comprises a resin pad having a flow path communicating with the attraction hole, and
the resin pad communicates with the attraction hole, and is connected to the heat plate via a metal member.

12. The heat treatment apparatus of claim 11,
wherein the metal member has a large-diameter portion.

13. The heat treatment apparatus of claim 11, further comprising:
an annular member connected to a lower portion of the heat plate with a supporting column therebetween, and
wherein the resin pad is located under the annular member.

14. The heat treatment apparatus of claim 1, further comprising:
a central exhaust unit configured to evacuate the inside of the processing space from a position of a ceiling portion of the chamber on a center side of the substrate on the heat plate, when viewed from above;
a peripheral exhaust unit configured to evacuate the inside of the processing space from a position of the ceiling portion on a peripheral side of the substrate on the heat plate as compared to the central exhaust unit, when viewed from above; and
a controller,
wherein the supply mechanism comprises another gas supply provided at the ceiling portion and configured to supply a gas toward the substrate on the heat plate,
wherein the another gas supply comprises:
a first discharge hole located above a peripheral portion of the substrate on the heat plate;
a second discharge hole located above a central portion of the substrate on the heat plate; and
a gas distribution space in which the gas introduced into the another gas supply is distributed into the first discharge hole and the second discharge hole, and
wherein the controller performs a control such that, during the heat treatment, a supply from the another gas supply and an evacuation by the peripheral exhaust unit are carried on and an evacuation by the central exhaust unit is enhanced from a middle of the heat treatment, and performs a control such that a flow rate of the gas supplied to the gas distribution space is increased in a period during which the evacuation by the central exhaust unit is enhanced.

15. A heat treatment method of heat-treating a substrate having a metal-containing resist film formed thereon, the heat treatment method comprising:
placing the substrate on a heat plate configured to support and heat the substrate; and
heat-treating the substrate on the heat plate,
wherein the heat-treating of the substrate comprises:
evacuating a processing space in which a heat treatment is performed; and
supplying a gas to the processing space, and
wherein, in the supplying of the gas, a high concentration gas, whose CO₂ concentration is adjusted to be higher than that of an ambient atmosphere around a chamber in which the processing space is formed, is supplied to the processing space.

16. The heat treatment method of claim 15,
wherein, in the supplying of the gas, the high concentration gas is supplied toward the substrate on the heat plate from a position at a side of the substrate on the heat plate and below the processing space, and a moisture-containing gas is supplied toward the substrate on the heat plate from a ceiling portion of the chamber.

17. The heat treatment method of claim 15,
wherein, in the supplying of the gas, the high concentration gas is supplied toward the substrate on the heat plate from a position at a side of the substrate on the heat plate and below the processing space and from a ceiling portion of the chamber.

18. The heat treatment method of claim 15,
wherein, in the supplying of the gas, the high concentration gas is supplied toward the substrate on the heat plate from a ceiling portion of the chamber, and a moisture-containing gas is supplied toward the substrate on the heat plate from a position at a side of the substrate on the heat plate and below the processing space.

19. The heat treatment method of claim 15,
wherein, in the supplying of the gas, a flow rate of the high concentration gas is reduced from a middle of the heat treatment.

20. A computer-readable recording medium having stored thereon computer-executable instructions that, in response to execution, cause a heat treatment apparatus to perform a heat treatment method as claimed in claim 15.
